(19) United States
(12) Patent Application Publication
(10) Pub. No.: US 2020/0051637 A1
(43) Pub. Date: Feb. 13, 2020

(54) METHOD FOR OPERATING MEMORY ARRAY

(71) Applicant: MACRONIX INTERNATIONAL CO., LTD., Hsinchu (TW)

(72) Inventors: Tao-Yuan LIN, Taipei City (TW); I-Chen YANG, Miaoli County (TW); Yao-Wen CHANG, Zhubei City (TW)

(21) Appl. No.: 16/057,864

(22) Filed: Aug. 8, 2018

(51) Int. Cl. G11C 16/04; G11C 16/10; G11C 16/08; G11C 16/14; G11C 16/32

(52) U.S. Cl. CPC G11C 16/0483; G11C 16/10; G11C 16/32; G11C 16/14; G11C 16/08

(57) ABSTRACT

A method for operating a memory array is provided. The memory array comprises a first NAND memory string comprising a i^{th} memory cell, a i−1^{th} memory cell, a i^{th} word line, and a i−1^{th} word line. The i^{th} memory cell and the i−1^{th} memory cell are arranged in a sequent order with a series electrical connection. The i^{th} word line is electrically connected to the i^{th} memory cell. The i−1^{th} word line is electrically connected to the i−1^{th} memory cell. The method for operating the memory array comprises in an operating time interval, performing a program inhibiting process to the i^{th} memory cell, and simultaneously performing a first process to the i^{th} memory cell. The program inhibiting process comprises providing a first pre-turn on voltage to the i^{th} word line. The first process comprises providing a second pre-turn on voltage to the i−1^{th} word line.

### BACKGROUND

### Technical Field

The disclosure relates to a method for operating a memory array, and particularly to a method for operating a memory array for improving device stability.

### Description of the Related Art

As critical dimensions of devices in integrated circuits shrink toward perceived limits of manufacturing technologies, designers have been looking to techniques to achieve greater storage capacity, and to achieve lower costs per bit. Technologies being pursued include a 3D (three-dimensional) NAND memory having multiple layers of memory cells on a single chip and operations performed therefor. However, current memory arrays have unstable data storage problems.

### SUMMARY

The present disclosure relates to a method for operating a memory array.

According to an embodiment, a method for operating a memory array is disclosed. The memory array comprises a first NAND memory string, a second NAND memory string, a i^{th} word line and a i−1^{th} word line. Each of the first NAND memory string and the second NAND memory string comprises a i^{th} memory cell and a i−1^{th} memory cell arranged in a sequent order with a series electrical connection. Both of the i^{th} memory cells of the first NAND memory string and the second NAND memory string are electrically connected to the i^{th} word line. Both of the i−1^{th} memory cells of the first NAND memory string and the second NAND memory string are electrically connected to the i−1^{th} word line. The method for operating the memory array comprises in an operating time interval, providing a first pass voltage and then a program voltage to the i^{th} word line, and providing a second pass voltage to the i−1^{th} word line. The program voltage is used for programming the i^{th} memory cell of the second NAND memory string. The second pass voltage is higher than the first pass voltage. A program inhibiting process is performed to the i^{th} memory cell of the first NAND memory string during the operating time interval.

According to an embodiment, a method for operating a memory array is disclosed. The memory array comprises a first NAND memory string. The first NAND memory string comprises a i^{th} memory cell, a i−1^{th} memory cell, a i^{th} word line, and a i−1^{th} word line. The i^{th} memory cell and the i−1^{th} memory cell are arranged in a sequent order with a series electrical connection. The i^{th} word line is electrically connected to the i^{th} memory cell. The i−1^{th} word line is electrically connected to the i−1^{th} memory cell. The method for operating the memory array comprises in an operating time interval, performing a program inhibiting process to the i^{th} memory cell, and simultaneously performing a first process to the i−1^{th} memory cell. The program inhibiting process comprises providing a first pre-turn on voltage to the i^{th} word line. The first process comprises providing a second pre-turn on voltage to the i−1^{th} word line.

The above and other embodiments of the disclosure will become better understood with regard to the following detailed description of the non-limiting embodiment(s). The following description is made with reference to the accompanying drawings.

### BRIEF DESCRIPTION OF THE DRAWINGS

FIG. 1 shows a memory array.

FIG. 2 is a voltage sequence diagram of the method for operating the memory array according to an embodiment.

FIG. 3 is a three dimensional view of a portion of a memory structure of a NAND string of a memory array according to an embodiment.

FIG. 4 illustrates a cross-section view of the memory structure along AA line in FIG. 3.

### DETAILED DESCRIPTION

Embodiments disclosed herein relate to a method for operating a memory array which can improve stability for a memory device.

The illustrations may not be necessarily drawn to scale, and there may be other embodiments of the present disclosure which are not specifically illustrated. Thus, the specification and the drawings are to be regard as an illustrative sense rather than a restrictive sense. Moreover, the descriptions disclosed in the embodiments of the disclosure such as detailed construction, manufacturing steps and material selections are for illustration only, not for limiting the scope of protection of the disclosure. The steps and elements in details of the embodiments could be modified or changed according to the actual needs of the practical applications. The disclosure is not limited to the descriptions of the embodiments. The illustration uses the same/similar symbols to indicate the same/similar elements.

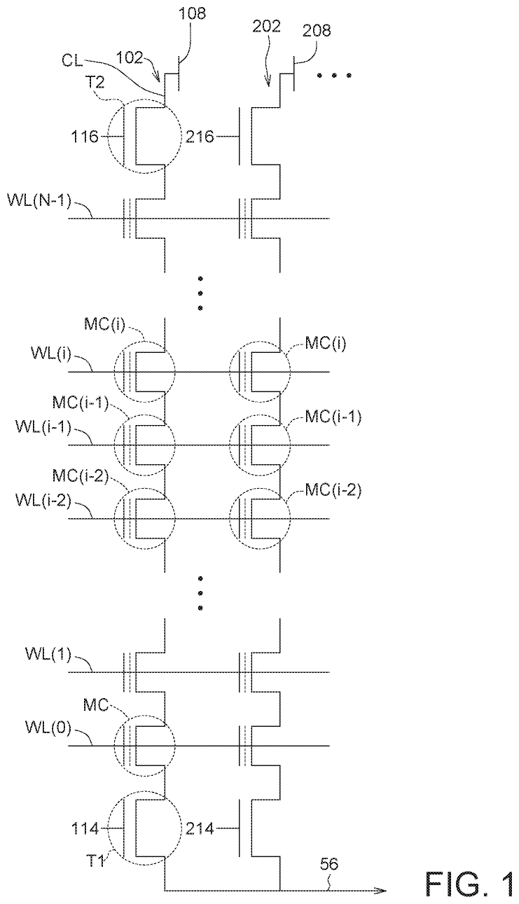

FIG. 1 shows a memory array. The memory comprises a first NAND memory string 102 and a second NAND memory string 202. The first NAND memory string 102 and the second NAND memory string 202 may comprise N memory cells MC electrically connected to each other with a series electrical connection, and N word lines are electrically connected to the corresponding N memory cells MC. The N word lines comprises a word line WL(0) electrically connected to an end memory cell MC, a word line WL(N−1) electrically connected to an opposing end memory cell MC, and other word lines (a word line WL(1) . . . etc.) arranged in order between the word line WL(0) and the word line WL(N−1). A string select switch T1 is electrically connected between the opposing end memory cell MC and a reference line 56.

The first NAND memory string 102 has a channel line CL electrically connected between the reference line 56 (e.g. common source line (CSL)) and a reference line 108 (e.g. bit line (BL), which can be indicated as a bit line BL−1 of the first NAND memory string 102 herein). A select line 114 (e.g. ground select line (GSL), which can be indicated as a ground select line GSL−1 herein) is electrically connected to the string select switch T1 of the first NAND memory string 102. The first NAND memory string 102 has a string select switch T2 electrically connected between the opposing end memory cell MC and the reference line 108. A select line 116 (e.g. string select line (SSL), which can be indicated as a string select line SSL−1 of the first NAND memory string 102) is electrically connected to the string select switch T2 of the first NAND memory string 102.

The second NAND memory string 202 has a channel line CL electrically connected between the reference line 56 (e.g. common source line (CSL)) and a reference line 208 (e.g. bit line (BL), which can be indicated as a bit line BL−2 of the second NAND memory string 202 herein). A select line 214 (e.g. ground select line (GSL), which can be indicated as a ground select line GSL−2 of the second NAND memory string 202 herein) is electrically connected to the string select switch T1 of the second NAND memory string 202. The second NAND memory string 202 has a string select switch T2 electrically connected between the opposing end memory cell MC and the reference line 208. A select line 216 (e.g. string select line (SSL), which can be indicated as a string select line SSL−2 of the second NAND memory string 202 herein) is electrically connected to the string select switch T2 of the second NAND memory string 202.

An operating method for the memory array according to a concept of the present disclosure may be understood with a i^{th} memory cell MC(i), a i−1^{th} memory cell MC(i−1), a i−2^{th} memory cell MC(i−2) arranged in order with a series electrical connection in the N memory cells MC, and an i^{th} word line WL(i), a i−1^{th} word line WL(i−1) and a i−2^{t} word line WL(i−2) arranged in order in the N word lines. The i^{th} memory cells MC(i) of the first NAND memory string 102 and the second NAND memory string 202 are commonly and electrically connected to the i^{th} word line WL(i). The i−1^{m} memory cells MC(i−1) of the first NAND memory string 102 and the second NAND memory string 202 are commonly and electrically connected to the i−1^{th} word line WL(i−1). The i−2^{th} memory cells MC(i−2) of the first NAND memory string 102 and the second NAND memory string 202 are commonly and electrically connected to the i−2^{th} word line WL(i−2).

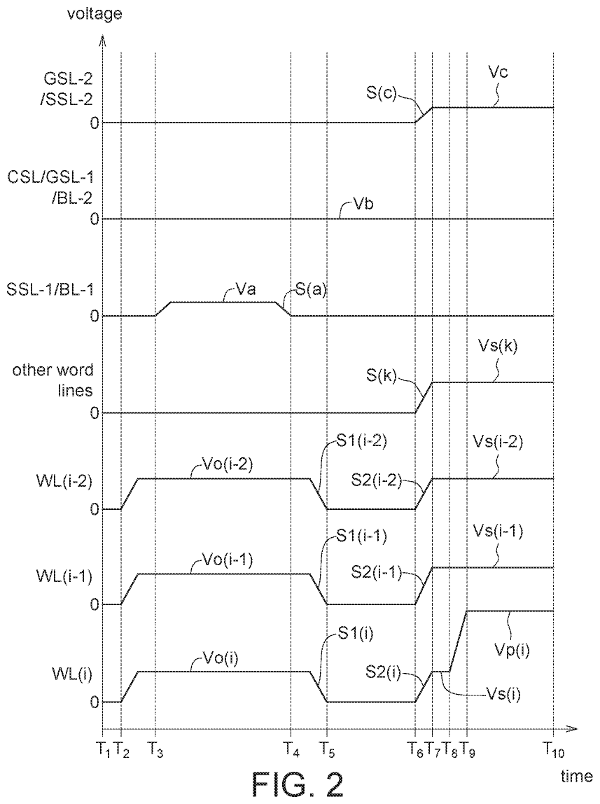

FIG. 1 and FIG. 2 are referred at the same time. FIG. 2 is a voltage (bias) sequence diagram of the method for operating the memory array according to an embodiment. A vertical axis represents voltages (or biases) provided to the common source line (CSL) (i.e. reference line 56), the ground select line (GSL−1) (i.e. select line 114) of the first NAND memory string 102, the ground select line (GSL−2) (i.e. select line 214 of the second NAND memory string 202), the i^{th} word line WL(i), the i−1^{m} word line WL(i−1), the i−2^{th} word line WL(i−2), the other word lines, the string select line (SSL−1) (i.e. select line 116) of the first NAND memory string 102, the string select line (SSL−2) (i.e. select line 216) of the second NAND memory string 202, the bit line (BL−1) (i.e. reference line 108) of the first NAND memory string 102, and the bit line (BL−2) (i.e. reference line 208) of the second NAND memory string 202. A horizontal axis represents a time, comprising a time point T1, a time point T2 . . . a time point T10 in a sequent order.

In the method for operating the memory array, in an operating time interval from the time point T1 to the time point T10, a programming process is performed to the i^{th} memory of the second NAND string 202, and simultaneously a program inhibiting process is performed to the i^{th} memory cell MC(i) of the first NAND string 102. The i^{th} memory of the second NAND string 202 is transformed from an erased state to a programmed state by the programming process. Meanwhile, a first process is performed to the i−1^{th} memory cell MC(i−1) of the first NAND string 102. A state of the i−1^{th} memory cell MC(i−1) of the first NAND string 102 is not changed by the first process. In addition, a second process may be performed to the i−2^{th} memory cell MC(i−2) of the first NAND string 102 simultaneously. A state of the i−2^{th} memory cell MC(i−2) of the first NAND string 102 is not changed by the second process.

The program inhibiting process performed to the i^{th} memory cell MC(i) of the first NAND string 102 and the programming process performed to the i^{th} memory cell MC(i) of the second NAND string 202 may comprise providing a pre-turn on voltage Vo(i) (first pre-turn on voltage), then a pass voltage Vs(i) (first pass voltage), and then a program voltage Vp(i) to the i^{th} word line WL(i). The program voltage Vp(i) is decided for programming the i^{th} memory cell MC(i) of the second NAND string 202. A state of i^{th} memory cell MC(i) of the first NAND string 102 is not changed by the program voltage Vp(i). In other words, the i^{th} memory cell MC(i) of the first NAND string 102 is still in a program inhibited state after the program voltage Vp(i). In an embodiment, the program inhibiting process performed to the i^{th} memory cell MC(i) of the first NAND string 102 and the programming process performed to the i^{th} memory cell MC(i) of the second NAND string 202 comprise providing a pulse voltage S1(i) of the time point T2 to the time point T5 to the i^{th} word line WL(i). The pulse voltage S1(i) may comprise the pre-turn on voltage Vo(i). The pre-turn on voltage Vo(i) may be applied to turn on the i^{th} word line WL(i). A pulse voltage S2(i) of the time point T6 to the time point T10 may be provided to the i^{th} word line WL(i). The pulse voltage S2(i) may comprise the pass voltage Vs(i) maintaining from the time point T7 to the time point T8, and may also comprise the program voltage Vp(i) maintaining from the time point T9 to the time point T10. The i^{th} word line WL(i) may be provided with a voltage of 0V during other time intervals.

The first process performed to the i−1^{th} memory cell MC(i−1) of the first NAND memory string 102 may comprise providing a pre-turn on voltage Vo(i−1) (second pre-turn on voltage) and then a pass voltage Vs(i−1) (second pass voltage) to the i−1^{th} word line WL(i−1). As shown in FIG. 2, a pulse voltage S1(i−1) of the time point T2 to the time point T5 may be provided to the i−1^{th} word line WL(i−1). The pulse voltage S1(i−1) may comprise the pre-turn on voltage Vo(i−1). The pre-turn on voltage Vo(i−1) may be applied for turn on the i−1^{th} word line WL(i−1). A pulse voltage S2(i−1) of the time point T6 to the time point T10 may be provided to the i−1^{th} word line WL(i−1). The pulse voltage S2(i−1) may comprise the pass voltage Vs(i−1) from the time point T7 to the time point T10. A turn-off voltage (such as 0V) may be provided to the i−1^{th} word line WL(i−1) during other time intervals. In an embodiment, the first process is performed to the i−1^{th} memory cell MC(i−1) in an erased state. In another embodiment, the first process is performed to the i−1^{th} memory cell MC(i−1) being in a programmed state resulted from a programming process before the operating time interval (i.e. before the time point T1).

The second process performed to the i−2^{th} memory cell MC(i−2) of the first NAND memory string 102 may comprise providing a pre-turn on voltage Vo(i−2) (third pre-turn on voltage) and then a pass voltage Vs(i−2) ((third pass voltage) to the i−2^{th} word line WL(i−2). As shown in FIG. 2, a pulse voltage S1(i−2) of the time point T2 to the time point T5 may be provided to the i−2^{th} word line WL(i−2). The pulse voltage S1(i−2) may comprise the pre-turn on voltage Vo(i−2). The pre-turn on voltage Vo(i−2) may be applied for turn on the i−2^{t} word line WL(i−2). A pulse voltage S2(i−2) of the time point T6 to the time point T10 may be provided to the i−2^{th} word line WL(i−2). The pulse voltage S2(i−2) may comprise the pass voltage Vs(i−2) maintaining from the time point T7 to the time point T10. A turn-off voltage (such as 0V) may be provided to the i−2^{th} word line WL(i−2) during other time intervals. In an embodiment, the second process is performed to the i−2^{th} memory cell MC(i−2) in an erased state. In another embodiment, the second process is performed to the i−2^{th} memory cell MC(i−2) being in a programmed state resulted from a programming process before the operating time interval (i.e. before the time point T1).

As to the other memory cells MC, a pass voltage Vs(k) (fourth pass voltage) may be provided to the corresponding word lines. As shown in FIG. 2, a turn-off voltage (such as 0V) may be provided to the corresponding word lines during a time interval from the time point T1 to the time point T6. Then, a pulse voltage S(k) from the time point T6 to the time point T10 may be provided to the other word lines. The pulse voltage S(k) may comprise the pass voltage Vs(k) maintaining from the time point T7 to the time point T10.

In embodiments, the pass voltage Vs(i−1) may be larger than the pass voltage Vs(i). The pass voltage Vs(i−1) may be also lower than the program voltage Vp(i). The pass voltage Vs(i−1) may be higher than the pass voltage Vs(i−2). The pass voltage Vs(i−1) may be higher than the pass voltage Vs(k).

For example, the pass voltage Vs(i), the pass voltage Vs(i−2), and the pass voltage Vs(k) may be 4V to 10V. In an embodiment, the pass voltage Vs(i), the pass voltage Vs(i−2), and the pass voltage Vs(k) may be the same value, and may be identical to the pre-turn on voltage Vo(i), the pre-turn on voltage Vo(i−1), and the pre-turn on voltage Vo(i−2). The present disclosure is not limited thereto.

Before providing the pass voltages Vs(i), Vs(i−1), Vs(i−2), Vs(k) to the word lines, for example, a pulse voltage S(a) may be provided to the bit line (BL−1) and the string select line (SSL−1) (select line 116) of the first NAND memory string 102 from a time point T3 to a time point T4. The pulse voltage S(a) comprises a voltage Va (e.g. 5V). The voltage Va provided to the bit line (BL−1) is a pre-charge voltage for the bit line (BL−1). The voltage Va provided to the string select line (SSL−1) may be used for turning on the string select switch T2 of the first NAND memory string 102. The bit line (BL−1) and the string select line (SSL−1) may be provided with a voltage of 0V during the other time intervals, wherein the string select switch T2 may be in an off state.

During providing the pass voltages Vs(i), Vs(i−1), Vs(i−2) and Vs(k) to the word lines, a pulse voltage S(c) may be provided to the ground select line (GSL−2) and the string select line (SSL−2) of the second NAND memory string 202 from the time point T6 to the time point T10. The pulse voltage S(c) comprises a turn on voltage Vc (e.g. about 4V) maintaining from the time point T7 to the time point T10. The ground select line (GSL−2) and the string select line (SSL−2) may be provided with a voltage of 0V during the other time intervals.

Voltages Vb provided to the common source line (CSL), the ground select line (GSL−1) of the first NAND memory string 102, and the bit line(BL−2) of the second NAND memory string 202 may be 0V.

In embodiments, the pass voltage Vs(i−1) higher than the pass voltage Vs(i) provided to the i^{th} memory cell MC(i) is provided to the i−1^{th} word line WL(i−1) during programming the i^{th} memory cell MC(i) of the first NAND memory string 102, which can reduce a shift degree of a threshold voltage for the i^{th} memory cell MC(i) of the first NAND memory string 102 caused from the programming process for the i^{th} memory of the second NAND memory string 202. In other words, the i^{th} memory cell MC(i) of the first NAND memory string 102 is not disturbed. Additionally/alternatively, the pre-turn on voltages Vo(i), Vo(i−1), Vo(i−2) are provided to the word lines before the pass voltages, which can reduce the shift degree of the threshold voltage for the i^{th} memory cell MC(i) of the first NAND memory string 102 caused from the programming process to the i^{th} memory of the second NAND memory string 202. In particular, in a condition with the i−1^{th} memory cell MC(i−1) of the first NAND memory string 102 in a programmed state resulted from a programming process before the operating time interval, a reduction to the shift of the threshold voltage for the i^{th} memory cell MC(i) is significant.

In a comparative example, during the operating time interval, no pre-charge voltage (Va) is provided to the bit line of the first NAND memory string 102, and no pre-turn on voltage is provided to the word lines, and the pass voltages provided to the word lines are all the same voltage. Even the pass voltages are high up to 10V, the threshold voltage of the i^{th} memory cell MC(i) of the first NAND memory string 102 still shifts by about 0.4V due to an influence with the 1^{th} memory cell MC(i) of the second NAND memory string 202 in a programmed state resulted from the programming process. In another comparative example, during the operating time interval, there is pre-charge voltage (Va) provided to the bit line of the first NAND memory string 102, no pre-turn on voltage is provided to the word line of the first NAND memory string 102, and the pass voltages provided to the word lines are all the same. In this condition, there is still a significant shift of the threshold voltage of the i^{th} memory cell MC(i) of the first NAND memory string 102 due to an influence with the 1^{th} memory cell MC(i) of the second NAND memory string 202 of a programmed state resulted from the programming process until the pass voltages is at least 8V, and even up to 10V.

On the contrary, in an embodiment, during the operating time interval, there are pre-charge voltage (Va) provided to the bit line of the first NAND memory string 102, the pre-turn on voltages (Vo(i), Vo(i−1), Vo(i−2)) provided to the word lines, and the pass voltage Vs(i−1) provided to the i−1^{th} word line WL(i−1) and being higher than the other pass voltages (Vs(i), Vs(i−2), Vs(k)) provided to the other word lines. In this situation, the pass voltages (such as 4V) (for the other word lines) lower than the comparative example can achieve the shift of threshold voltage of the i^{th} memory cell MC(i) being about 0V. In particular, the shift of threshold voltage of the i^{th} memory cell MC(i) is also about 0V with the adjacent i−1^{th} memory cell MC(i−1) of the first NAND memory string 102 in a programmed state resulted from a programming process before the operating time interval.

Accordingly, the operating method according the concept of the present disclosure can used for maintaining electrical property to a memory cell during the operating. Therefore, the memory array can have a stable electrical characteristic and data storing property.

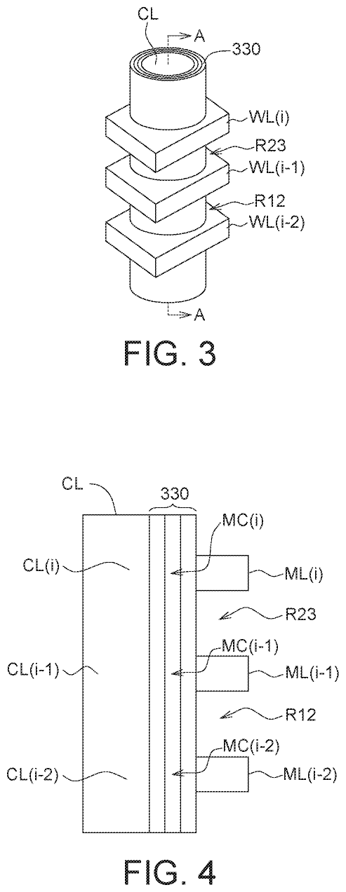

In the embodiment, the NAND memory string comprises a memory structure having a gate-all-around (GAA) structure. For example, FIG. 3 and FIG. 4 may be referred. FIG. 3 is a three dimensional view of the memory structure. FIG. 4 illustrates a cross-section view of the memory structure along AA line in FIG. 3. the NAND memory string comprises the channel line CL, the word lines (such as the i^{th} word line WL(i), the i−1^{th} word line WL(i−1) and the i−2^{t} word line WL(i−2)) and a memory layer 330 between the channel line CL and the word lines. The channel line CL is a pillar channel line. The memory layer 330 is a pillar memory layer, which may be regarded as an annular or hollow pillar memory layer surrounding the channel line CL. The word lines surround the memory layer 330. The memory cells (the i^{th} memory cell MC(i), the i−1^{t}h memory cell MC(i−1), and the i−2^{th} memory cell MC(i−2)) are defined at cross-points between the channel line CL and the word lines (the i^{th} word line WL(i), the i−1^{th} word line WL(i−1) and the i−2^{th} word line WL(i−2)). The channel line CL may comprise a channel CL(i) of the i^{th} memory cell MC(i), a channel CL(i−1) of the i^{th} memory cell MC(i−1), and a channel CL(i−2) of the i^{th} memory cell MC(i−2), etc. The word lines may be spaced apart from each other by an insulating layer disposed in regions corresponding to regions R12, R23 between the word lines.

The channel line CL may comprise a poly-silicon material, silicon dioxide, or other suitable semiconductor materials, etc. The memory layer 330 may comprise a charge trapping structure of any kind, such as an oxide-nitride-oxide (ONO) structure, or an oxide-nitride-oxide-nitride-oxide (BE-SONOS) structure, etc. For example, the charge trapping film may use a nitride such as silicon nitride, or other materials such as poly-silicon, etc. For example, a high-K material, comprising a metal oxide such as Al2O3, HfO2, etc. with a thickness of 10-50 angstroms, may be disposed between the memory layer 330 and a gate electrode (for example, having a material comprising a metal).

Embodiments may extend to other variations according to the concepts according to the present disclosure.

For example, the NAND memory string is not limited to a vertical channel structure, and may use a single gate vertical channel structure, a vertical gate structure or the like. The memory cells may be floating gate memory cells, nitride-trapping memory cells or the like. The memory cells may be single-level cells, multi-level cells, triple-level cells or the like.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

1. A method for operating a memory array, wherein the memory array comprises a first NAND memory string, a second NAND memory string, an i^{th} word line, an i−1^{th} word line, and an i−2^{th} word line, each of the first NAND memory string and the second NAND memory string comprises an i^{th} memory cell, an i−1^{th} memory cell, and an i−2^{th} memory cell arranged in a sequent order with a series electrical connection, both of the i^{th} memory cells of the first NAND memory string and the second NAND memory string are electrically connected to the i^{th} word line, both of the i−1^{th} memory cells of the first NAND memory string and the second NAND memory string are electrically connected to the i−1^{th} word line, both of the i−2^{th} memory cells of the first NAND memory string and the second NAND memory string are electrically connected to the i−2^{th} word line,
the method for operating the memory array comprises in an operating time interval, providing a first pass voltage and then a program voltage to the i^{th} word line, providing a second pass voltage to the i−1^{th} word line, and providing a third pass voltage to the i−2^{th} word line, wherein the program voltage is used for programming the i^{th} memory cell of the second NAND memory string, the second pass voltage is higher than the first pass voltage, and the second pass voltage is higher than the third pass voltage, a program inhibiting process is performed to the i^{th} memory cell of the first NAND memory string during the operating time interval.

2. The method for operating the memory array according to claim 1, wherein the first NAND memory string comprises a channel line and a reference line electrically connected with each other, the channel line comprises channels of the i^{th} memory cell and the i−1^{th} memory cell of the first NAND memory string, the method for operating the memory array comprises providing a pre-charge voltage to the reference line before providing the first pass voltage to the i^{th} word line and providing the second pass voltage to the i−1^{th} word line.

3. The method for operating the memory array according to claim 2, wherein the first NAND memory string comprises a string select switch electrically connected between the reference line and the i^{th} memory cell, the method for operating the memory array comprises turning off the string select switch during the providing the first pass voltage and the program voltage to the i^{th} word line, and/or the providing the second pass voltage to the i−1^{th} word line.

4. The method for operating the memory array according to claim 1, wherein
the program inhibiting process comprises providing a pre-turn on voltage to the i^{th} word line before the first pass voltage and the program voltage; and/or
a first process is performed to the i−1^{th} memory cell of the first NAND memory string, the first process comprises providing the pre-turn on voltage to the i−1^{th} word line before the second pass voltage.

5. The method for operating the memory array according to claim 4, wherein the first NAND memory string comprises word lines and memory cells in a series electrical connection, the word lines are respectively electrically connected to corresponding one of the memory cells, the word lines comprises the i^{th} word line and the i−1^{th} word line,
the method for operating the memory array further comprises providing a turn-off voltage to a word line of the word lines other than the i^{th} word line and the i−1^{th} word line during providing the pre-turn on voltage.

6. The method for operating the memory array according to claim 1, wherein the second pass voltage is maintained during providing the first pass voltage and the program voltage.

7. The method for operating the memory array according to claim 1, wherein the second pass voltage is lower than the program voltage.

8. The method for operating the memory array according to claim 1,
further comprising performing a first process to the i−1^{th} memory cell, and simultaneously performing a second process to the i−2^{th} memory cell wherein the first process comprises the providing the second pass voltage to the i−1^{th} word line, the second process comprises the providing the third pass voltage to the i−2^{th} word line.

9. The method for operating the memory array according to claim 8, wherein the first NAND memory string comprises word lines and memory cells in a series electrical connection, the word lines are respectively electrically connected to corresponding one of the memory cells, the word lines comprises the i^{th} word line, the i−1^{th} word line, and the i−2^{th} word line,
the method for operating the memory array comprises providing a fourth pass voltage to a word line of the word lines other than the i^{th} word line, the i−1^{th} word line, and the i−2^{th} word line during the providing the second pass voltage to the i−1^{th} word line, the fourth pass voltage is lower than the second pass voltage.

10. The method for operating the memory array according to claim 1, wherein a first process is performed to the i−1^{th} memory cell, and a programming process is performed to the i^{th} memory cell of the second NAND memory string, the program inhibiting process, the first process and the programming process are performed simultaneously.

11. A method for operating a memory array, wherein the memory array comprises a first NAND memory string, the first NAND memory string comprising:
an i^{th} memory cell, an i−1^{th} memory cell, and an i−2^{th} memory cell arranged in a sequent order with a series electrical connection;
an i^{th} word line electrically connected to the i^{th} memory cell;
an i−1^{th} word line electrically connected to the i−1^{th} memory cell; and
an i−2^{th} word line electrically connected to the i−2^{th} memory cell,
wherein the method for operating the memory array comprises:
in an operating time interval, performing a program inhibiting process to the i^{th} memory cell, and simultaneously performing a first process to the i−1^{th} memory cell, wherein the program inhibiting process comprises providing a first pre-turn on voltage and then a first pass voltage to the i^{th} word line, the first process comprises providing a second pre-turn on voltage and then a second pass voltage to the i−1^{th} word line; and
providing a third pass voltage to the i−2^{th} word line during providing the second pass voltage to the i−1^{th} word line,
wherein the second pass voltage is higher than the first pass voltage, and the second pass voltage is higher than the third pass voltage.

12. The method for operating the memory array according to claim 11, wherein the program inhibiting process comprises providing a program voltage to the i^{th} word line after the first pre-turn on voltage.

13. The method for operating the memory array according to claim 12, wherein the first pass voltage is before the program voltage.

14. The method for operating the memory array according to claim 13, wherein the memory array further comprises a second NAND memory string, each of the first NAND memory string and the second NAND memory string comprises the i^{th} memory cell and the i−1 memory cell arranged in a sequent order with a series electrical connection, both of the i^{th} memory cells of the first NAND memory string and the second NAND memory string are electrically connected to the i^{th} word line, both of the i−1^{th} memory cells of the first NAND memory string and the second NAND memory string are electrically connected to the i−1^{th} word line, the program voltage is used for programming the i^{th} memory cell of the second NAND memory string during the program inhibiting process performed to the i^{th} memory cell of the first NAND memory string.

15. The method for operating the memory array according to claim 11, wherein the first NAND memory string comprises a channel line and a reference line electrically connected with each other, the channel line comprises channels of the i^{th} memory cell and the i−1^{th} memory cell, the method for operating the memory array comprises providing a pre-charge voltage to the reference line in a time interval during the providing the first pre-turn on voltage to the i^{th} word line and the providing the second pre-turn on voltage to the i−1^{th} word line.

16. The method for operating the memory array according to claim 15, wherein the first NAND memory string comprises a string select switch electrically connected between the reference line and the i^{th} memory cell, the method for operating the memory array comprises turning off the string select switch during the providing the pre-charge voltage to the reference line.

17. The method for operating the memory array according to claim 11,
comprising performing a second process to the i−2^{th} memory cell during the first process performed to the i−1^{th} memory cell, wherein the second process comprises providing a third pre-turn on voltage to the i−2^{th} word line.

18. The method for operating the memory array according to claim 17, wherein the first NAND memory string comprises word lines and memory cells in a series electrical connection, the word lines are respectively electrically connected to corresponding one of the memory cells, the word lines comprises the i^{th} word line, the i−1^{th} word line and the i−2^{th} word line, the method for operating the memory array further comprises providing a turn-off voltage to a word line of the word lines other than the i^{th} word line, the i−1^{th} word line and the i−2^{th} word line during the providing the second pre-turn on voltage to the i−1^{th} word line and the providing the third pre-turn on voltage to the i−2^{th} word line.

19. The method for operating the memory array according to claim 11, wherein, the first process is performed to the i−1th memory cell being in an erased state or being programmed before the operating time interval.

20. The method for operating the memory array according to claim 11, wherein the first pre-turn on voltage and the second pre-turn on voltage are simultaneously provided by pulse voltages having the same wave shape.
